(19) United States
(12) Patent Application Publication
(10) Pub. No.: US 2026/0293154 A1
(43) Pub. Date: Sep. 24, 2026

(54) STORAGE DEVICE

(71) Applicant: Kioxia Corporation, Tokyo (JP)

(72) Inventor: Hiroyuki KANAYA, Yokohama (JP)

(21) Appl. No.: 19/332,386

(22) Filed: Sep. 18, 2025

(30) Foreign Application Priority Data
Mar. 21, 2025 (JP) 2025-047007

(51) Int. Cl. H10B 61/00; H10N 50/01; H10N 50/10

(52) U.S. Cl. CPC H10B 61/10; H10N 50/01; H10N 50/10

(57) ABSTRACT

A storage device includes first and second lower wires extending in a first direction; first and second upper wires extending in a second direction; a first memory cell provided between the first lower wire and the first upper wire, a second memory cell provided between the first lower wire and the second upper wire, and a third memory cell provided between the second lower wire and the first upper wire; and an insulating portion provided between the first lower wire and the second lower wire. Each of the first to third memory cells includes a variable resistance storage element and a switching element stacked in a third direction. The switching element of each of the first to third memory cells includes a lower electrode and an upper electrode, and the first to third memory cells share a switching material layer.

### CROSS-REFERENCE TO RELATED APPLICATION(S)

This application is based upon and claims the benefit of priority from Japanese Patent Application No. 2025-047007, filed Mar 21, 2025, the entire contents of which are incorporated herein by reference.

### FIELD

Embodiments described herein relate generally to a storage device.

### BACKGROUND

A storage device such that a multiple of memory cells, each of which includes a variable resistance storage element, such as a magnetoresistive effect element, and a selector (a switching element), are stacked on a semiconductor substrate is proposed.

### DESCRIPTION OF THE DRAWINGS

FIG. 1 is a perspective view schematically showing a basic configuration of a storage device according to an embodiment.

FIG. 2A is a sectional view schematically showing a basic configuration of the storage device according to an embodiment.

FIG. 2B is a sectional view schematically showing a basic configuration of the storage device according to an embodiment.

FIG. 3A is a sectional view schematically showing one example of a configuration of a main body portion of a magnetoresistive effect element of the storage device according to the embodiment.

FIG. 3B is a sectional view schematically showing another example of a configuration of a main body portion of a magnetoresistive effect element of the storage device according to the embodiment.

FIG. 4A is a sectional view schematically showing one portion of a method of manufacturing the storage device according to the embodiment.

FIG. 4B is a sectional view schematically showing one portion of a method of manufacturing the storage device according to the embodiment.

FIG. 5A is a sectional view schematically showing one portion of a method of manufacturing the storage device according to the embodiment.

FIG. 5B is a sectional view schematically showing one portion of a method of manufacturing the storage device according to the embodiment.

FIG. 6A is a sectional view schematically showing one portion of a method of manufacturing the storage device according to the embodiment.

FIG. 6B is a sectional view schematically showing one portion of a method of manufacturing the storage device according to the embodiment.

FIG. 7A is a sectional view schematically showing one portion of a method of manufacturing the storage device according to the embodiment.

FIG. 7B is a sectional view schematically showing one portion of a method of manufacturing the storage device according to the embodiment.

FIG. 8A is a sectional view schematically showing one portion of a method of manufacturing the storage device according to the embodiment.

FIG. 8B is a sectional view schematically showing one portion of a method of manufacturing the storage device according to the embodiment.

FIG. 9A is a sectional view schematically showing one portion of a method of manufacturing the storage device according to the embodiment.

FIG. 9B is a sectional view schematically showing one portion of a method of manufacturing the storage device according to the embodiment.

FIG. 10A is a sectional view schematically showing a configuration of a first modification of the storage device according to the embodiment.

FIG. 10B is a sectional view schematically showing a configuration of the first modification of the storage device according to the embodiment.

FIG. 11A is a sectional view schematically showing a configuration of a second modification of the storage device according to the embodiment.

FIG. 11B is a sectional view schematically showing a configuration of the second modification of the storage device according to the embodiment.

FIG. 12A is a sectional view schematically showing a configuration of a third modification of the storage device according to the embodiment.

FIG. 12B is a sectional view schematically showing a configuration of the third modification of the storage device according to the embodiment.

### DETAILED DESCRIPTION

Embodiments provide a storage device that has excellent properties and reliability, and which is such that neighboring memory cells can be reliably electrically isolated.

In general, according to one embodiment, a storage device includes first and second lower wires extending in a first direction and arranged adjacent to each other; first and second upper wires extending in a second direction intersecting the first direction and arranged adjacent to each other; a first memory cell provided between the first lower wire and the first upper wire, a second memory cell provided between the first lower wire and the second upper wire, and a third memory cell provided between the second lower wire and the first upper wire; and an insulating portion provided between the first lower wire and the second lower wire. Each of the first, second, and third memory cells includes a variable resistance storage element and a switching element stacked in a third direction intersecting the first and second directions. The switching element of each of the first to third memory cells includes a lower electrode and an upper electrode, and the first to third memory cells share a switching material layer, wherein the switching material layer includes a respective portion positioned between the lower electrode and the upper electrode of each of the first to third memory cells, covering an upper face of the lower electrode, and extending along at least an upper portion of a side face of the lower electrode. The switching material layer further includes a plurality of layer portions, each of the layer portions provided on a side face of the variable resistance storage element included in one of the first to third memory cells, an upper face of the first or second lower wire, or an upper face of the insulating portion.

Hereafter, an embodiment will be described with reference to the drawings.

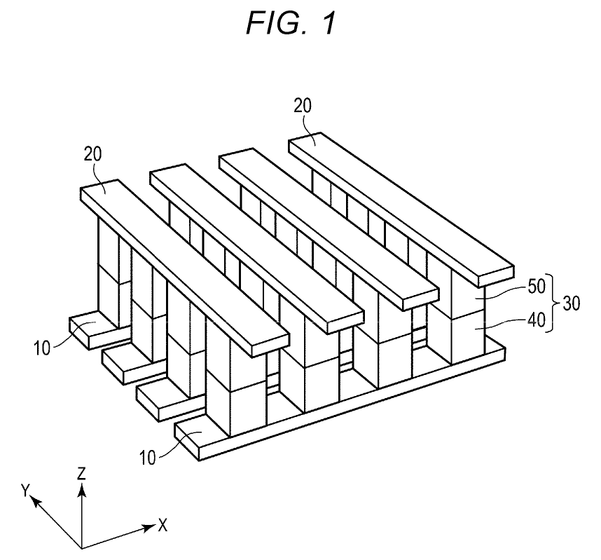

FIG. 1 is a perspective view schematically showing a basic configuration of a storage device according to an embodiment.

A storage device according to the present embodiment includes a multiple of lower wires 10, each of which extends in an X direction, a multiple of upper wires 20, each of which extends in a Y direction, and a multiple of memory cells 30 provided between the multiple of lower wires 10 and the multiple of upper wires 20.

One of the lower wire 10 or the upper wire 20 corresponds to a word line, while the other of the lower wire 10 or the upper wire 20 corresponds to a bit line.

Each memory cell 30 includes a magnetoresistive effect element (a non-volatile variable resistance storage element) 40 and a selector (a two-terminal switching element) 50, and the magnetoresistive effect element 40 and the selector 50 are of a structure stacked in a Z direction.

The X direction, the Y direction, and the Z direction are directions that intersect each other. Specifically, the X direction, the Y direction, and the Z direction are perpendicular to each other.

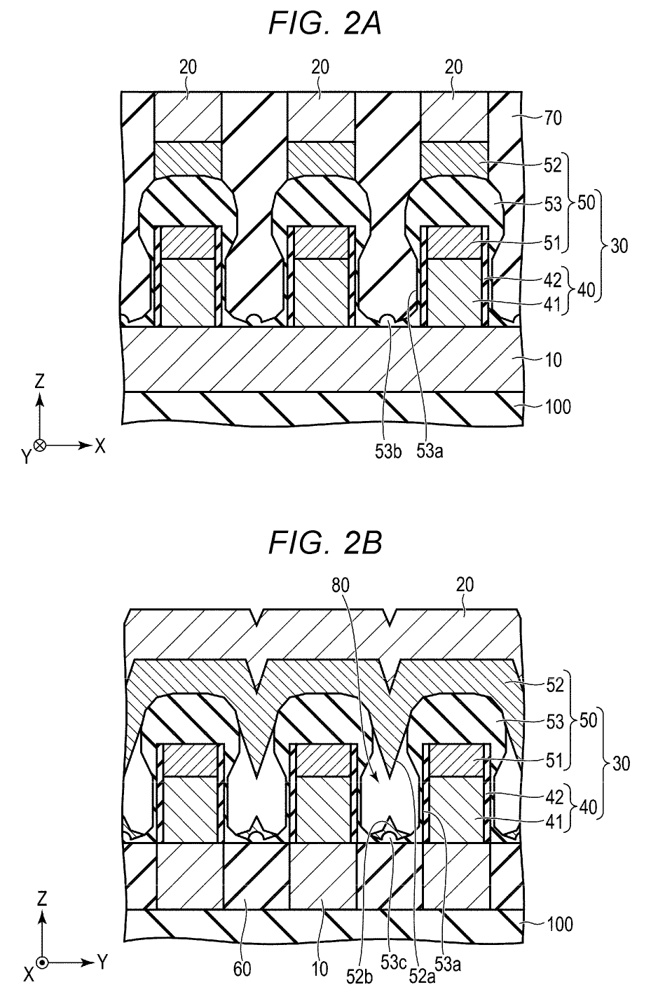

Each of FIGS. 2A and 2B is a sectional view schematically showing a specific configuration of a storage device according to the present embodiment. FIG. 2A is a sectional view in the X direction, and FIG. 2B is a sectional view in the Y direction.

A storage device according to the present embodiment is provided on a lower region including a semiconductor substrate (not shown), an insulating layer 100, and the like, and includes the multiple of lower wires 10, the multiple of upper wires 20, the multiple of memory cells 30, a multiple of insulating portions 60, and a multiple of insulating portions 70.

As already mentioned, each of the multiple of lower wires 10 extends in the X direction, and each of the multiple of upper wires 20 extends in the Y direction. The lower wire 10 and the upper wire 20 are formed of a conductive material such as tungsten (W).

The multiple of memory cells 30 are provided between the multiple of lower wires 10 and the multiple of upper wires 20, and each memory cell 30 includes the magnetoresistive effect element 40 and the selector 50 stacked in the Z direction.

The magnetoresistive effect element 40 is a spin-transfer torque (STT) magnetic tunnel junction (MTJ) element having perpendicular magnetism, and includes a main body portion 41 and a side wall insulating layer 42.

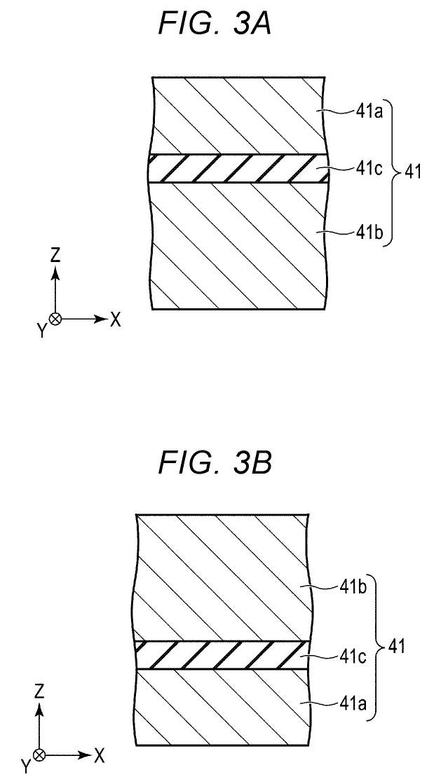

FIGS. 3A and 3B are sectional views schematically showing one example and another example respectively of a configuration of the main body portion 41 of the magnetoresistive effect element 40.

The main body portion 41 includes a storage layer (a first magnetic layer) 41a, a reference layer (a second magnetic layer) 41b, and a tunnel barrier layer (a non-magnetic layer) 41c.

The storage layer 41a is a ferromagnetic layer having a variable magnetization direction, and is formed of, for example, a CoFeB layer containing cobalt (Co), iron (Fe), and boron (B). A variable magnetization direction means that a magnetization direction changes with respect to a predetermined write current.

The reference layer 41b is a ferromagnetic layer having a fixed magnetization direction, and is formed of, for example, a CoFeB layer containing cobalt (Co), iron (Fe), and boron (B) and a superlattice layer of cobalt (Co) and platinum (Pt). A fixed magnetization direction means that a magnetization direction does not change with respect to a predetermined write current.

The tunnel barrier layer 41c is an insulating layer provided between the storage layer 41a and the reference layer 41b, and is formed of, for example, an MgO layer containing magnesium (Mg) and oxygen (O).

When the magnetization direction of the storage layer 41a is parallel to the magnetization direction of the reference layer 41b, the main body portion 41 of the magnetoresistive effect element 40 is in a state of low resistance having a relatively low resistance, and when the magnetization direction of the storage layer 41a is antiparallel to the magnetization direction of the reference layer 41b, the main body portion 41 of the magnetoresistive effect element 40 is in a state of high resistance having a relatively high resistance. Consequently, the magnetoresistive effect element 40 can store binary data in accordance with the state of resistance of the main body portion 41.

The side wall insulating layer 42 has a function of protecting the main body portion 41, and includes a portion provided along a side wall of the main body portion 41 and a portion provided along a side wall of a lower electrode 51 of the selector 50, to be described hereafter. The side wall insulating layer 42 is formed of, for example, an insulating material such as silicon nitride (SiN).

The selector 50 is provided on an upper layer side of the magnetoresistive effect element 40, and includes the lower electrode 51, an upper electrode 52, and a selector material layer (a switching material layer) 53.

The lower electrode 51 includes a portion containing a predetermined conductive material as a main component, and also functions as an upper electrode of the magnetoresistive effect element 40. The predetermined conductive material is selected from, for example, carbon (C), tungsten (W), and titanium nitride (TiN).

The upper electrode 52 includes a portion containing a predetermined conductive material as a main component. The predetermined conductive material is selected from, for example, carbon (C) and tungsten nitride (WN).

A material of the selector material layer 53 is basically an insulating material with, for example, a material containing zirconium oxide (ZrOx) as a main component being used as the material of the selector material layer 53. Owing to a material containing zirconium oxide being used as the material of the selector material layer 53, the selector 50 having excellent properties can be obtained. Also, a material (ZnTe) containing zinc (Zn) and tellurium (Te) may be added to zirconium oxide as the material of the selector material layer 53. Owing to this kind of material being used in the selector material layer 53, the properties of the selector 50 can be caused to further improve.

A material containing hafnium (Hf) oxide as a main component or a material containing scandium (Sc) oxide as a main component can also be used instead of a material containing zirconium (Zr) oxide as a main component as the material of the selector material layer 53. These materials are all materials that are difficult to process using reactive ion etching (RIE).

The selector material layer 53 includes a portion positioned between the lower electrode 51 and the upper electrode 52, and is provided in such a way as to cover an upper face of the lower electrode 51 and at least an upper portion of a side face of the lower electrode 52. In the present embodiment, the side wall insulating layer 42 is also provided on a side face (side wall) of the lower electrode 51, because of which the selector material layer 53 is provided in such a way as to cover the upper face of the lower electrode 51 and at least an upper portion of a side face of the side wall insulating layer 42.

As the selector material layer 53 has the heretofore described kind of form, the selector material layer 53 also includes a portion positioned on an outer side of a portion positioned between the lower electrode 51 and the upper electrode 52.

Note that the selector material layers 53 included in memory cells 30 that neighbor each other are separated from each other. A more specific description is as below.

Lower wires 10 that neighbor each other are first and second lower wires 10, and upper wires 20 that neighbor each other are first and second upper wires 20. Also, the memory cell 30 provided between the first lower wire 10 and the first upper wire 20 is a first memory cell 30, the memory cell 30 provided between the first lower wire 10 and the second upper wire 20 is a second memory cell 30, and the memory cell 30 provided between the second lower wire 10 and the first upper wire 20 is a third memory cell 30.

When stipulating as described above, the selector material layer 53 included in the first memory cell 30 and the selector material layer 53 included in the second memory cell 30 are separated from each other in at least an upper side region of a plane including a lower face of the lower electrode 51 included in the first memory cell 30 and a lower face of the lower electrode 51 included in the second memory cell 30.

In the same way, the selector material layer 53 included in the first memory cell 30 and the selector material layer 53 included in the third memory cell 30 are separated from each other in at least an upper side region of a plane including the lower face of the lower electrode 51 included in the first memory cell 30 and a lower face of the lower electrode 51 included in the third memory cell 30.

Also, when stipulating as described above, the upper electrode 52 included in the first memory cell 30 and the upper electrode 52 included in the third memory cell 30 are provided continuously. More specifically, the upper electrode 52 included in the first memory cell 30 and the upper electrode 52 included in the third memory cell 30 are provided continuously along the first upper wire 20.

The selector 50 has a characteristic of shifting from an off state to an on state when a voltage applied between the lower electrode 51 and the upper electrode 52 reaches a threshold voltage or greater.

Consequently, when a voltage is applied between the lower wire 10 and the upper wire 20, and the voltage applied between the lower electrode 51 and the upper electrode 52 reaches the threshold voltage or greater, the selector 50 shifts to an on state. Because of this, current flows into the magnetoresistive effect element 40, which is connected in series to the selector 50, and a write or a read with respect to the magnetoresistive effect element 40 can be carried out.

Each of the multiple of insulating portions 60 is provided between lower wires 10 that neighbor each other and extends in the X direction. That is, lower wires 10 that neighbor each other are isolated from each other by the insulating portion 60. Each insulating portion 60 is formed of, for example, an insulating material such as silicon oxide or silicon nitride.

Each of the multiple of insulating portions 70 includes a portion provided between upper wires 20 that neighbor each other and a portion provided between memory cells 30 that neighbor each other in the X direction and extends in the Y direction. That is, upper wires 20 that neighbor each other and memory cells 30 that neighbor each other in the X direction are isolated from each other by the insulating portion 70. Each insulating portion 70 is formed of, for example, an insulating material such as silicon oxide or silicon nitride.

A multiple of spaces 80 are provided one each on an upper side of each of the multiple of insulating portions 60. Each of the multiple of spaces 80 is provided between a multiple of the memory cells 30 that neighbor each other in the Y direction. That is, memory cells 30 that neighbor each other in the Y direction are isolated from each other by the space 80. A protruding portion 52a protrudes from the upper electrode 52 into an upper portion of the space 80, and a material portion 52b formed of the material of the upper electrode 52 is provided in a lower portion of the space 80.

Also, a layer portion 53a is provided on a side face of the magnetoresistive effect element 40 (the side face of the side wall insulating layer 42), a layer portion 53b is provided on an upper face of the lower wire 10, and a layer portion 53c is provided on an upper face of the insulating portion 60. To describe focusing on the heretofore described first memory cell 30, the layer portion 53a is provided on the side face of the magnetoresistive effect element 40 included in the first memory cell 30, the layer portion 53b is provided on the upper face of the first lower wire 10, and the layer portion 53c is provided on the upper face of the insulating portion 60 between the first lower wire 10 and the second lower wire 10.

The aforementioned layer portions 53a, 53b, and 53c include a material the same as the material of the selector material layer 53. The layer portions 53a, 53b, and 53c are formed when forming the selector material layer 53.

In the present embodiment, the layer portion 53a is provided continuously from the selector material layer 53 but may also be provided non-continuously from the selector material layer 53. Also, the layer portion 53b is provided continuously from the layer portion 53abut may also be provided non-continuously from the layer portion 53a. In the same way, the layer portion 53c is provided continuously from the layer portion 53abut may also be provided non-continuously from the layer portion 53a.

Also, in the present embodiment, all of the layer portions 53a, 53b, and 53c are provided, but it is sufficient that at least one of the layer portions 53a, 53b, and 53c is provided.

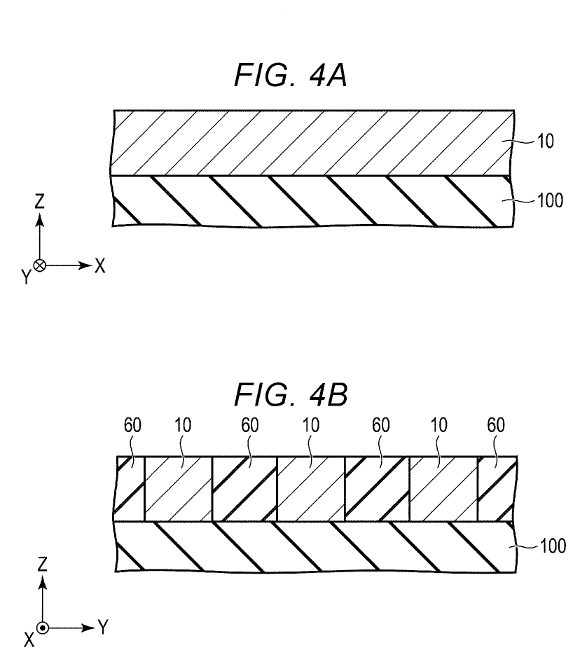

Next, a method of manufacturing a storage device according to the present embodiment will be described, with reference to FIGS. 4A and 4B to FIGS. 9A and 9B. FIGS. 4A to 9A are sectional views in the X direction, and FIGS. 4B to 9B are sectional views in the Y direction.

Firstly, as shown in FIGS. 4A and 4B, the multiple of lower wires 10 and the multiple of insulating portions 60 are formed on the insulating layer 100. Specifically, the multiple of lower wires 10 and a multiple of grooves are formed, and furthermore, the multiple of grooves are filled with an insulating layer, thereby forming the multiple of insulating portions 60.

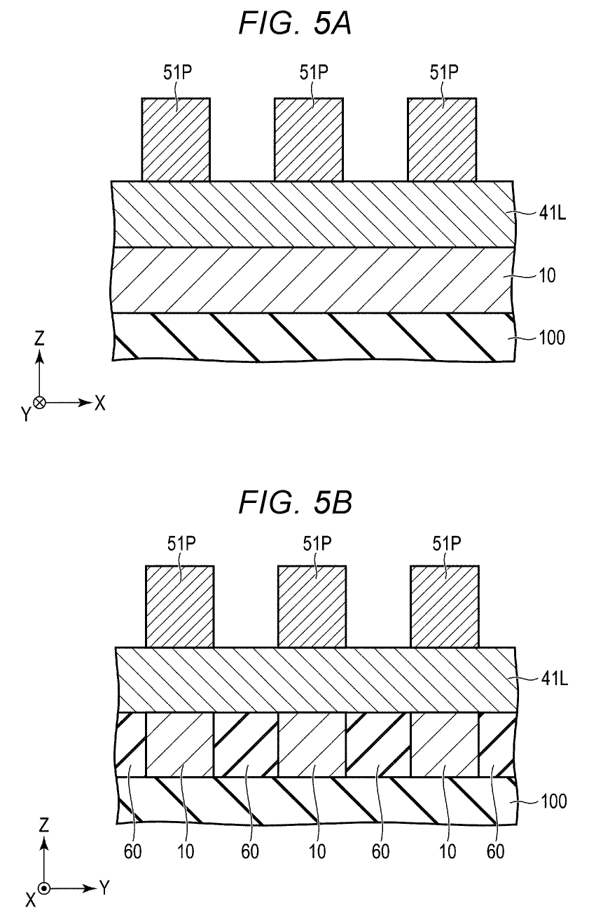

Next, as shown in FIGS. 5A and 5B, a main body portion layer 41L of a magnetoresistive effect element is formed by deposition on the structure obtained in the process of FIGS. 4A and 4B. Continuing, a pillar form pattern 51P is formed, using the conductive material used for the lower electrode 51 of a selector, on the main body portion layer 41L.

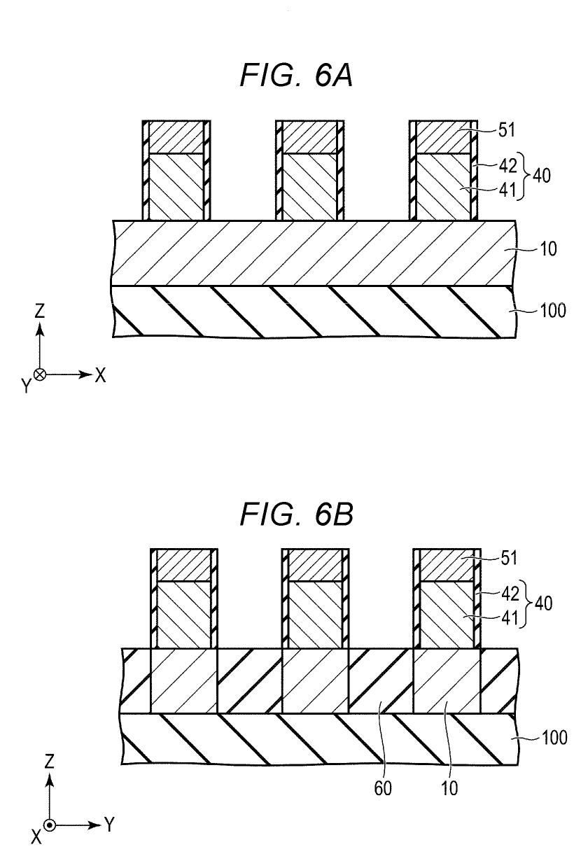

Next, as shown in FIGS. 6A and 6B, the main body portion layer 41L is etched using ion beam etching (IBE) or the like, using the pillar form pattern 51P as a mask, whereby the main body portion 41 of a magnetoresistive effect element is formed. Also, a thickness of the pillar form pattern 51P is reduced by the etching, whereby the lower electrode 51 of a selector is formed. Continuing, the side wall insulating layer 42 is formed on side walls of the main body portion 41 and lower electrode 51 obtained in this way. Because of this, the magnetoresistive effect element 40 including the main body portion 41 and the side wall insulating layer 42 is formed.

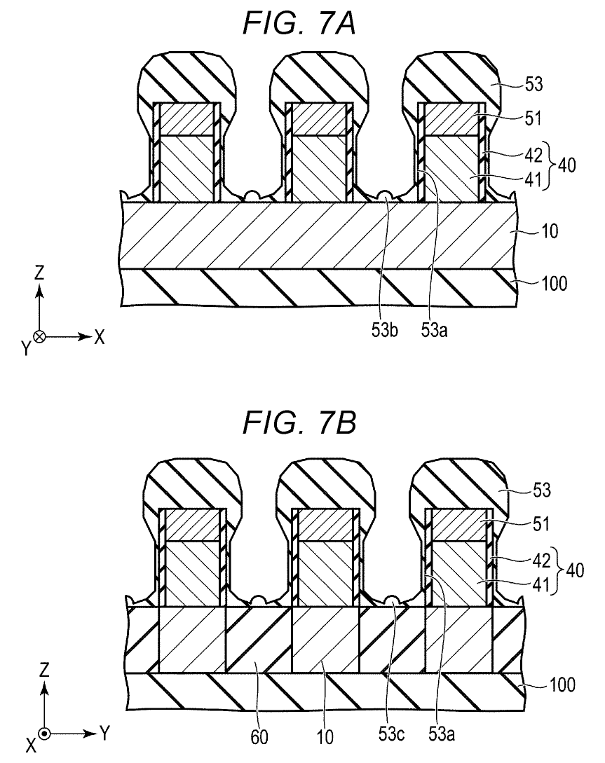

Next, as shown in FIGS. 7A and 7B, the selector material layer 53 is formed using a physical vapor deposition (PVD) such as sputtering. Owing to PVD being used, the selector material layer 53 is formed in such a way as to cover the upper face of the lower electrode 51 and at least an upper portion of the side face of the lower electrode 51 (the side face of the side wall insulating layer 42). Also, the selector material layers 53 are formed in such a way as to be separated from each other between neighboring memory cells.

Also, as the selector material layers 53 are formed in such a way as to be separated from each other between neighboring memory cells, the layer portion 53a is formed on the side face of the side wall insulating layer 42 of the magnetoresistive effect element 40, the layer portion 53b is formed on the upper face of the lower wire 10, and the layer portion 53c is formed on the upper face of the insulating portion 60 when forming the selector material layer 53.

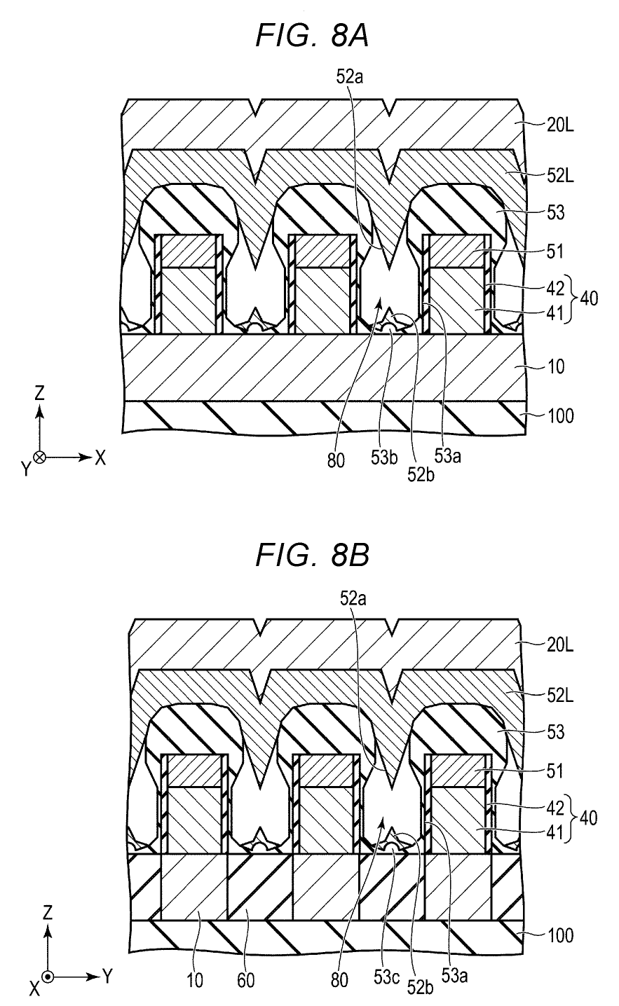

Next, as shown in FIGS. 8A and 8B, an upper electrode layer 52L and an upper wire layer 20L are formed using a PVD such as sputtering on the structure obtained in the process of FIGS. 7A and 7B.

As the selector material layer 53 has the heretofore described kind of form, an interval between neighboring selector material layers 53 is comparatively narrow. Also, the upper electrode layer 52L and the upper wire layer 20L are formed using a PVD. Because of this, a region between neighboring memory cells is not filled with the upper electrode layer 52L and the upper wire layer 20L, and the space 80 is formed. Also, the protruding portion 52a of the upper electrode layer 52L is formed in an upper portion of the space 80, and the material portion 52b, in which the material of the upper electrode layer 52L is accumulated, is formed in a lower portion of the space 80.

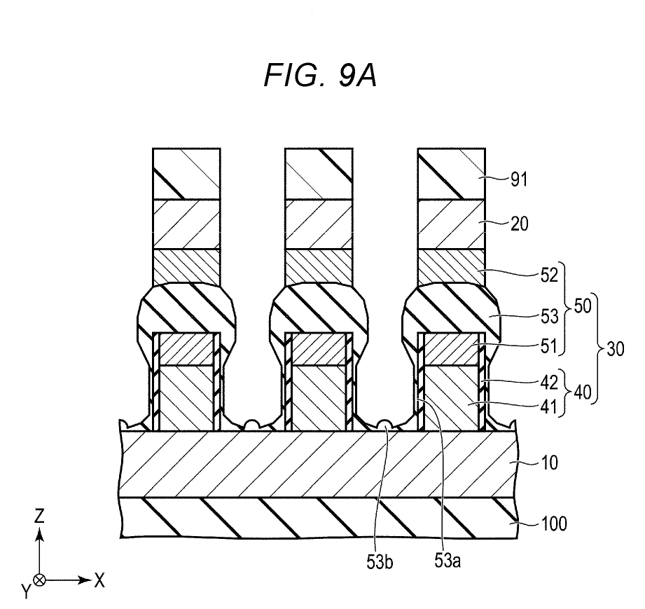

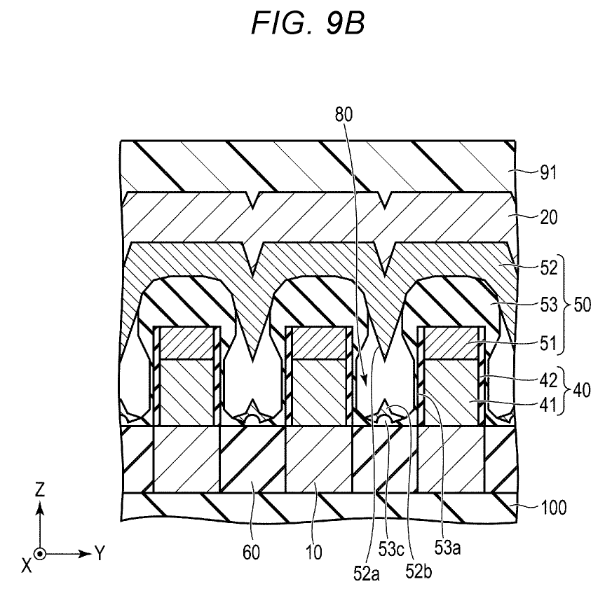

Next, as shown in FIGS. 9A and 9B, a master pattern 91 is formed on the upper wire layer 20L. Continuing, the upper wire layer 20L and the upper electrode layer 52L are etched using reactive ion etching (RIE), using the master pattern 91 as a mask. Owing to this etching, patterns of the upper wire 20 and the upper electrode 52 are formed. Because of this, the selector 50 including the lower electrode 51, the upper electrode 52, and the selector material layer 53 is formed, and the memory cell 30 including the magnetoresistive effect element 40 and the selector 50 is obtained. Also, the material portion 52b is removed from a region between memory cells 30 neighboring in the X direction, and the material portion 52b remains in a region between memory cells 30 neighboring in the Y direction.

Subsequently, the master pattern 91 is removed. Furthermore, the insulating portion 70 is formed by filling a region between upper wires 20 neighboring in the X direction and a region between memory cells 30 neighboring in the X direction with an insulating layer, whereby the kind of structure shown in FIGS. 2A and 2B is obtained.

As heretofore described, the present embodiment is such that owing to the selector material layer 53 being formed using a PVD, the selector material layer 53 is formed in such a way as to cover the upper face of the lower electrode 51 and at least an upper portion of the side face of the lower electrode 51 (the side face of the side wall insulating layer 42). Also, the selector material layers 53 are formed in such a way as to be separated from each other between neighboring memory cells 30. This means that in the present embodiment, the heretofore described kind of structure can be obtained without patterning the selector material layer 53. Because of this, a storage device that has excellent properties and reliability, and which is such that neighboring memory cells 30 can reliably be electrically isolated, can be obtained, as will be described below.

When memory cells are reduced in size and a degree of integration increases, accurately forming a selector material layer pattern using a dry etching such as RIE is not easy. In particular, when a material containing zirconium oxide (ZrOx) as a main component is used in a selector material layer, forming an accurate pattern is difficult. Furthermore, when a material such that a material (ZnTe) containing zinc and tellurium is added to zirconium oxide is used in the selector material layer, forming an accurate pattern is more difficult. That is, a compound containing zirconium, zinc, or tellurium has a high boiling point, and does not vaporize easily. Because of this, carrying out a dry etching of the heretofore described kind of material is not easy, and even when etching can be carried out, there is a problem in that an etched product becomes redeposited on a selector side wall. Consequently, obtaining a memory cell with excellent properties and reliability is difficult.

A structure such that selector material layers are not separated between neighboring memory cells is also conceivable, but when using this kind of structure, a situation such that neighboring memory cells cannot reliably be electrically isolated may occur. For example, when a misalignment occurs between an upper electrode and a lower electrode of a selector, a distance between an upper electrode of one selector and a lower electrode of the other selector decreases in neighboring selectors. As a result of this, the selector material layer shifts to an on state between the upper electrode of the one selector and the lower electrode of the other selector, and there is a possibility that an accurate memory action can no longer be obtained.

In the present embodiment, the heretofore described kind of structure can be obtained without carrying out a selector material layer patterning. Consequently, the heretofore described kind of problem can be avoided, and a storage device that has excellent properties and reliability, and which is such that neighboring memory cells can reliably be electrically isolated, can be obtained.

Also, in the present embodiment, the layer portions 53a, 53b, and 53c are formed when forming the selector material layer 53, but as the layer portions 53a, 53b, and 53c are not formed between the lower electrode 51 and the upper electrode 52, there is no adverse effect on an action of the selector 50. On the contrary, as the layer portion 53a is formed on the side face of the magnetoresistive effect element 40, the magnetoresistive effect element 40 can be effectively protected by the layer portion 53a during a subsequent etching process or the like.

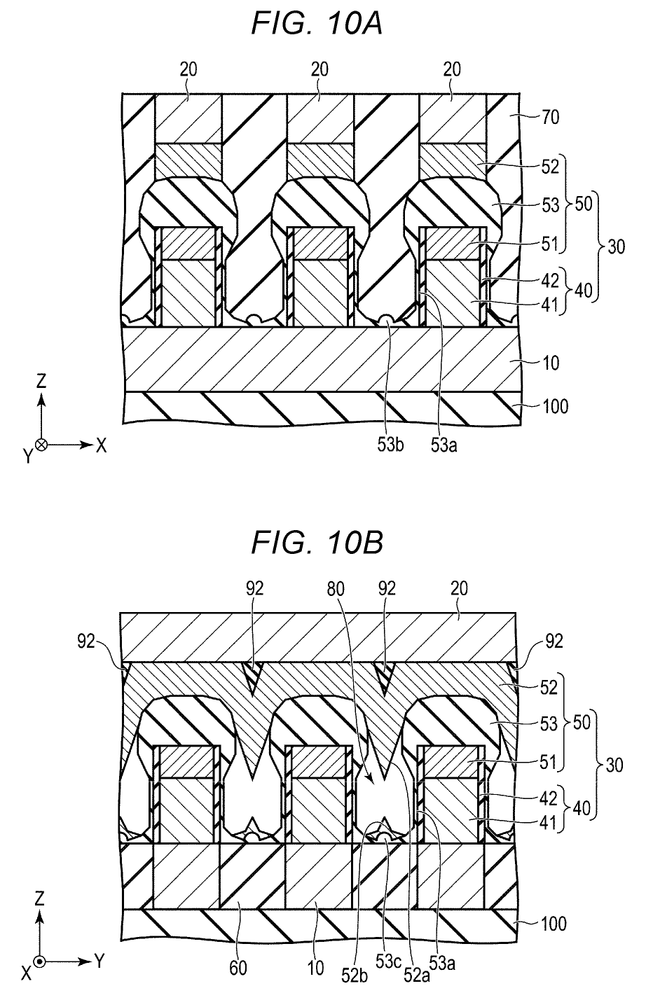

FIGS. 10A and 10B are sectional views schematically showing a configuration of a first modification of a storage device according to the present embodiment. FIG. 10A is a sectional view in the X direction, and FIG. 10B is a sectional view in the Y direction.

In the present modification, as shown in FIG. 10B, a multiple of insulating portions 92 are provided in a multiple of recessed portions provided in the upper electrode 52 of the selector 50.

When the upper electrode layer 52L is formed in the process of FIGS. 8A and 8B of the heretofore described embodiment, the space 80 is formed in a region between neighboring memory cells. Because of this, a recessed portion is formed in the upper electrode layer 52L above the space 80. In the present modification, an insulating layer is formed on the upper electrode layer 52L, the recessed portion is filled with the insulating layer, and furthermore, the insulating layer is planarized, leaving the insulating layer in the recessed portion only. After the upper wire layer 20L is formed on the structure obtained in this way, a structure of the present modification is obtained by carrying out the same processes as in the heretofore described embodiment.

In the present modification, the flat upper wire 20 can be formed by providing the multiple of insulating portions 92.

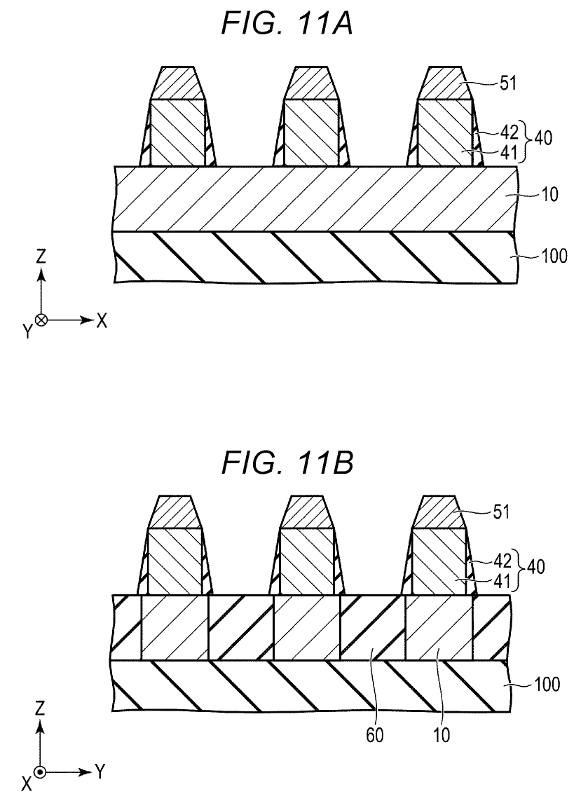

FIGS. 11A and 11B are sectional views schematically showing a configuration of a second modification of a storage device according to the present embodiment. FIG. 11A is a sectional view in the X direction, and FIG. 11B is a sectional view in the Y direction.

In the heretofore described embodiment, the side wall insulating layer 42 is also formed on the side wall of the lower electrode 51 in the process of FIGS. 6A and 6B, but in the present modification, the side wall insulating layer 42 is formed only on the side wall of the main body portion 41 of the magnetoresistive effect element 40, and is not formed on the side wall of the lower electrode 51. For example, when the side wall of the lower electrode 51 widens from an upper side toward a lower side, as shown in FIGS. 11A and 11B, the kind of structure of the present modification may be formed. Herein, there is no great loss of properties of the selector 50, even when a whole of the side wall of the main body portion 41 is not covered by the side wall insulating layer 42. That is, there is no great effect on the properties of the selector 50 itself.

The present modification is also such that after the kind of structure shown in FIGS. 11A and 11B is formed, the side wall insulating layer 42 and the lower electrode 51 obtain the kinds of structure shown in FIGS. 11A and 11B by the same kinds of process as those in FIGS. 7A and 7B to FIGS. 9A and 9B of the heretofore described embodiment being carried out, and with regard to other structures, a storage device having the same structure as the structure shown in FIGS. 2A and 2B of the heretofore described embodiment can be obtained.

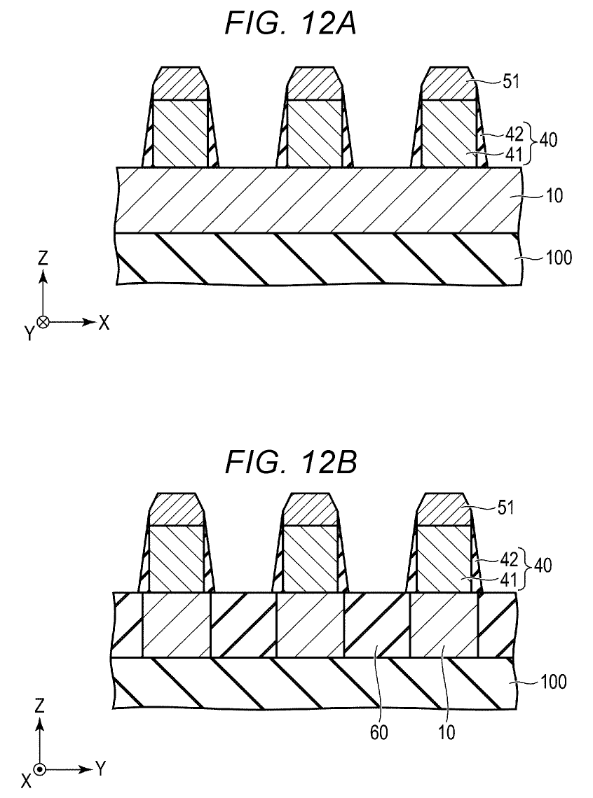

FIGS. 12A and 12B are sectional views schematically showing a configuration of a third modification of a storage device according to the present embodiment. FIG. 12A is a sectional view in the X direction, and FIG. 12B is a sectional view in the Y direction.

In the present modification, the side wall insulating layer 42 is formed on the side wall of the main body portion 41 of the magnetoresistive effect element 40 and the side wall of a lower portion of the lower electrode 51, but the side wall insulating layer 42 is not formed on the side wall of an upper portion of the lower electrode 51. For example, when the side wall of the upper portion of the lower electrode 51 widens from an upper side toward a lower side, as shown in FIGS. 12A and 12B, the kind of structure of the present modification may be formed.

The present modification is also such that after the kind of structure shown in FIGS. 12A and 12B is formed, the side wall insulating layer 42 and the lower electrode 51 obtain the kinds of structure shown in FIGS. 12A and 12B by the same kinds of process as those in FIGS. 7A and 7B to FIGS. 9A and 9B of the heretofore described embodiment being carried out, and with regard to other structures, a storage device having the same structure as the structure shown in FIGS. 2A and 2B of the heretofore described embodiment can be obtained.

In the heretofore described embodiment, a magnetoresistive effect element is used as a non-volatile variable resistance storage element, but another non-volatile variable resistance storage element may be used.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A storage device, comprising:
first and second lower wires extending in a first direction and arranged adjacent to each other;
first and second upper wires extending in a second direction intersecting the first direction and arranged adjacent to each other;
a first memory cell provided between the first lower wire and the first upper wire, a second memory cell provided between the first lower wire and the second upper wire, and a third memory cell provided between the second lower wire and the first upper wire; and
an insulating portion provided between the first lower wire and the second lower wire, wherein
each of the first, second, and third memory cells includes a variable resistance storage element and a switching element stacked in a third direction intersecting the first and second directions,
the switching element of each of the first to third memory cells includes a lower electrode and an upper electrode, and the first to third memory cells share a switching material layer, wherein the switching material layer includes a respective portion positioned between the lower electrode and the upper electrode of each of the first to third memory cells, covering an upper face of the lower electrode, and extending along at least an upper portion of a side face of the lower electrode, and
the switching material layer further includes a plurality of layer portions, each of the layer portions provided on a side face of the variable resistance storage element included in one of the first to third memory cells, an upper face of the first or second lower wire, or an upper face of the insulating portion.

2. The storage device according to claim 1, wherein the switching material layer included in the first memory cell and the switching material layer included in the second memory cell are separated from each other in at least an upper side region of a plane including a lower face of the lower electrode included in the first memory cell and a lower face of the lower electrode included in the second memory cell.

3. The storage device according to claim 1, wherein the switching material layer included in the first memory cell and the switching material layer included in the third memory cell are separated from each other in at least an upper side region of a plane including a lower face of the lower electrode included in the first memory cell and a lower face of the lower electrode included in the third memory cell.

4. The storage device according to claim 1, wherein the layer portion provided on the side face of the variable resistance storage element continuously extends from a portion of the switching material layer covering the upper face of the lower electrode.

5. The storage device according to claim 1, wherein the lower electrode further functions as an upper electrode of the variable resistance storage element.

6. The storage device according to claim 1, wherein the lower electrode includes a portion containing a conductive material selected from the group consisting of carbon, tungsten, and titanium nitride.

7. The storage device according to claim 1, wherein the upper electrode included in the first memory cell and the upper electrode included in the third memory cell continuously extend.

8. The storage device according to claim 1, wherein the switching material layer includes an insulating material.

9. The storage device according to claim 1, wherein the switching material layer includes a material selected from the group consisting of zirconium oxide, hafnium oxide, and scandium oxide.

10. The storage device according to claim 9, wherein the switching material layer includes zinc and tellurium.

11. The storage device according to claim 1, wherein the variable resistance storage element includes a main body portion, and a side wall insulating layer including a portion provided along a side wall of the main body portion.

12. The storage device according to claim 11, wherein the side wall insulating layer further includes a portion provided along a side wall of the lower electrode.

13. The storage device according to claim 11, wherein the layer portion provided on the side face of the variable resistance storage element extends along a side face of the side wall insulating layer.

14. The storage device according to claim 1, wherein the variable resistance storage element is a magnetoresistive effect element.

15. The storage device according to claim 1, wherein the switching element has a characteristic of shifting from an off state to an on state when a voltage applied between the lower electrode and the upper electrode reaches a threshold voltage or greater.

16. A method, comprising:
forming first and second lower wires extending in a first direction, wherein the first lower wire and the second wire are spaced from each other with an insulating portion;
forming a first memory cell and a second memory cell on the first lower wire, and a third memory cell on the second lower wire; and
forming first and second upper wires extending in a second direction intersecting the first direction, wherein, along a vertical direction, the first memory cell is interposed between the first lower wire and the first upper wire, the second memory cell is interposed between the first lower wire and the second upper wire, and the third memory cell is interposed between the second lower wire and the first upper wire;
wherein each of the first, second, and third memory cells includes a variable resistance storage element and a switching element stacked in the vertical direction;
wherein the switching element of each of the first to third memory cells includes a lower electrode and an upper electrode, and the first to third memory cells share a switching material layer, wherein the switching material layer includes a respective portion positioned between the lower electrode and the upper electrode of each of the first to third memory cells, covering an upper face of the lower electrode, and extending along at least an upper portion of a side face of the lower electrode; and
wherein the switching material layer further includes a plurality of layer portions, each of the layer portions provided on a side face of the variable resistance storage element included in one of the first to third memory cells, an upper face of the first or second lower wire, or an upper face of the insulating portion.
